(19) United States
(12) Patent Application Publication
(10) Pub. No.: US 2026/0181787 A1
(43) Pub. Date: Jun. 25, 2026

(54) ELECTRONIC PACKAGE STRUCTURE AND METHOD OF MANUFACTURING ELECTRONIC PACKAGE STRUCTURE

(71) Applicant: Unictron Technologies Corporation, Hsin-Chu (TW)

(72) Inventors: Ching-Jung Wang, Taoyuan City (TW); Hao-Ting Chiang, Taoyuan City (TW)

(73) Assignee: Unictron Technologies Corporation, Hsin-Chu (TW)

(21) Appl. No.: 19/078,238

(22) Filed: Mar. 12, 2025

(30) Foreign Application Priority Data
Dec. 19, 2024 (TW) 113213995

(51) Int. Cl. H05K 3/28; B29C 45/14; H01F 27/02; H01L 25/18; H05K 1/02

(52) U.S. Cl. CPC H05K 3/28; H01F 27/022; H05K 1/0284; H10W 90/00; B29C 45/1418; H05K 2203/1305

(57) ABSTRACT

An electronic package structure includes a ring-shaped electronic component, a chip, a first frame and a second frame. The chip is coupled to the ring-shaped electronic component. The first frame covers the ring-shaped electronic component and the chip from a first side. The second frame covers the ring-shaped electronic component and the chip from a second side, wherein the first side is opposite to the second side. The first frame and the second frame are combined with each other, such that the ring-shaped electronic component and the chip are sealed between the first frame and the second frame. Accordingly, complete waterproofing can be achieved without exposing internal components.

### BACKGROUND OF THE INVENTION

### 1. Field of the Invention

The invention relates to an electronic package structure and, more particularly, to an electronic package structure capable of achieving complete waterproofing without exposing internal components and a method of manufacturing the electronic package structure.

### 2. Description of the Prior Art

At present, a small coil equipped with a chip is packaged in a frame through an injection molding process. Since the coil is not rigid enough and is easily deformed, it is necessary to support the coil with ejector pins in a mold. After the frame is formed, supporting holes corresponding to the ejector pins will be formed in the appearance of the frame, such that the coil and/or the chip are exposed from the supporting holes and the waterproof requirement cannot be achieved.

### SUMMARY OF THE INVENTION

The invention provides an electronic package structure capable of achieving complete waterproofing without exposing internal components and a method of manufacturing the electronic package structure, so as to solve the aforesaid problems.

According to an embodiment of the invention, an electronic package structure comprises a ring-shaped electronic component, a chip, a first frame and a second frame. The chip is coupled to the ring-shaped electronic component. The first frame covers the ring-shaped electronic component and the chip from a first side. The second frame covers the ring-shaped electronic component and the chip from a second side, wherein the first side is opposite to the second side. The first frame and the second frame are combined with each other, such that the ring-shaped electronic component and the chip are sealed between the first frame and the second frame.

In an embodiment, the first frame is formed through a first injection molding process first and then the second frame is formed through a second injection molding process.

In an embodiment, a side of the first frame is formed with a plurality of recesses during the first injection molding process, a side of the second frame is formed with a plurality of protrusions during the second injection molding process, and the plurality of protrusions are embedded in the plurality of recesses.

In an embodiment, the ring-shaped electronic component is a coil or a circuit board.

In an embodiment, the first frame and the second frame are transparent.

According to an embodiment of the invention, a method of manufacturing an electronic package structure comprises steps of disposing a ring-shaped electronic component and a chip in a first mold, wherein the chip is coupled to the ring-shaped electronic component; forming a first frame in the first mold through a first injection molding process, such that the first frame covers the ring-shaped electronic component and the chip from a first side; disposing the ring-shaped electronic component, the chip and the first frame in a second mold; and forming a second frame in the second mold through a second injection molding process, such that the second frame covers the ring-shaped electronic component and the chip from a second side, the first frame and the second frame are combined with each other, and the ring-shaped electronic component and the chip are sealed between the first frame and the second frame, wherein the first side is opposite to the second side.

In an embodiment, the first mold comprises a first male mold and a first female mold, the first male mold is formed with a plurality of grooves and a plurality of protruding portions, and the plurality of grooves and the plurality of protruding portions are arranged in a ring shape at intervals. The step of disposing a ring-shaped electronic component and a chip in a first mold comprises steps of disposing the ring-shaped electronic component on the plurality of protruding portions, such that the plurality of protruding portions support the ring-shaped electronic component above the plurality of grooves; and covering the first female mold on the first male mold.

In an embodiment, a side of the first frame is formed with a plurality of recesses during the first injection molding process, and positions of the plurality of recesses correspond to positions of the plurality of protruding portions of the first male mold.

In an embodiment, a side of the second frame is formed with a plurality of protrusions during the second injection molding process, and the plurality of protrusions are embedded in the plurality of recesses.

In an embodiment, the second mold comprises a second male mold and a second female mold. The step of disposing the ring-shaped electronic component, the chip and the first frame in a second mold comprises steps of disposing the ring-shaped electronic component, the chip and the first frame in the second male mold, such that the first frame is in contact with the second male mold, and the ring-shaped electronic component is not in contact with the second male mold; and covering the second female mold on the second male mold.

In an embodiment, the ring-shaped electronic component is a coil or a circuit board.

In an embodiment, the first frame and the second frame are transparent.

As mentioned in the above, the invention packages the ring-shaped electronic component and the chip in the first frame and the second frame combined with each other. In an embodiment, the first frame may be formed through the first injection molding process first to cover the ring-shaped electronic component and the chip. At this time, the first frame can fix the ring-shaped electronic component with insufficient rigidity to prevent the ring-shaped electronic component from deforming. Then, the second frame may be formed through the second injection molding process, such that the first frame and the second frame are combined with each other. After the package is completed, there will be no holes formed in the appearance of the first frame and the second frame. Accordingly, the ring-shaped electronic component and the chip are sealed between the first frame and the second frame combined with each other, so as to achieve complete waterproofing without exposing internal components. The electronic package structure of the invention not only has fast processing speed, but also the mold can be modularized to increase production efficiency.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating an electronic package structure according to an embodiment of the invention.

FIG. 2 is an exploded view illustrating the electronic package structure shown in FIG. 1.

FIG. 3 is a perspective view illustrating the electronic package structure shown in FIG. 1 from another viewing angle.

FIG. 4 is an exploded view illustrating the electronic package structure shown in FIG. 3.

FIG. 5 is a schematic view illustrating a first injection molding process according to an embodiment of the invention.

FIG. 6 is a schematic view illustrating a second injection molding process according to an embodiment of the invention.

FIG. 7 is a flowchart illustrating a method of manufacturing the electronic package structure according to an embodiment of the invention.

### DETAILED DESCRIPTION

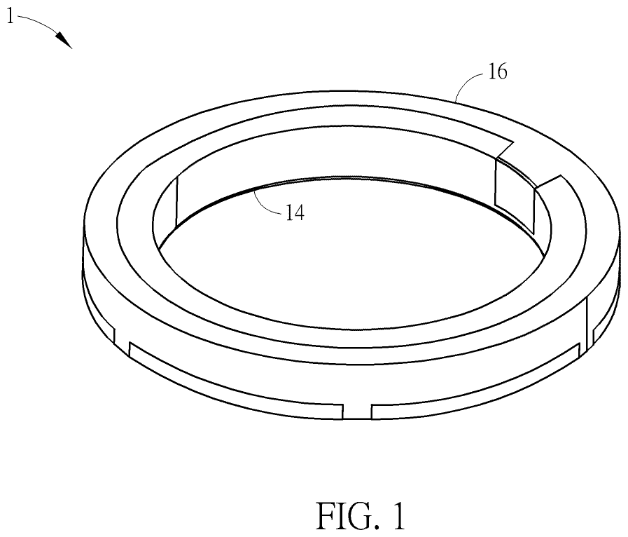

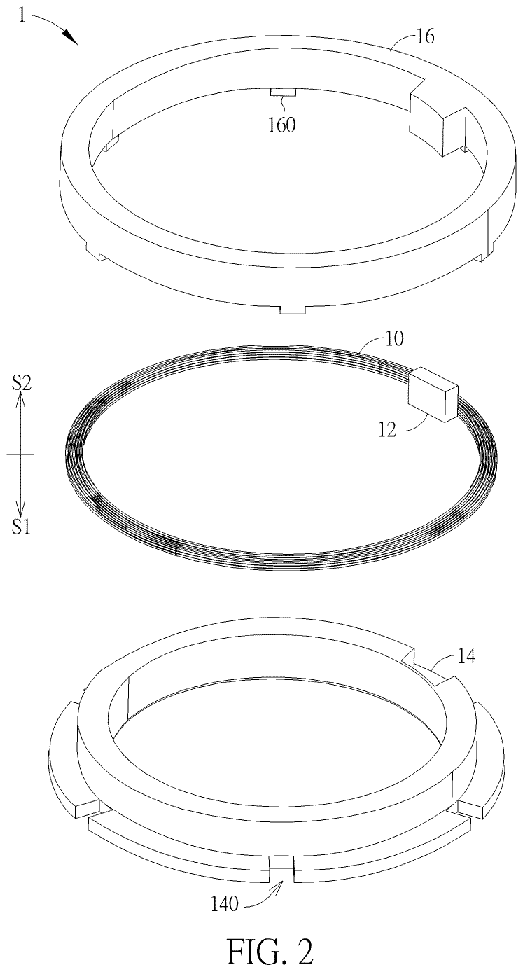

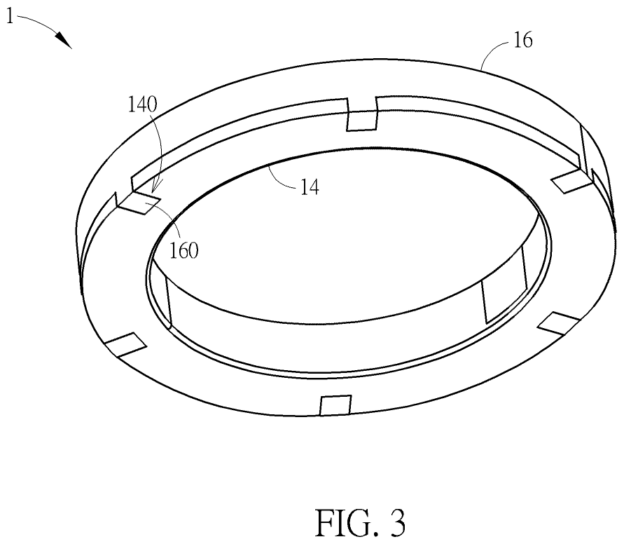

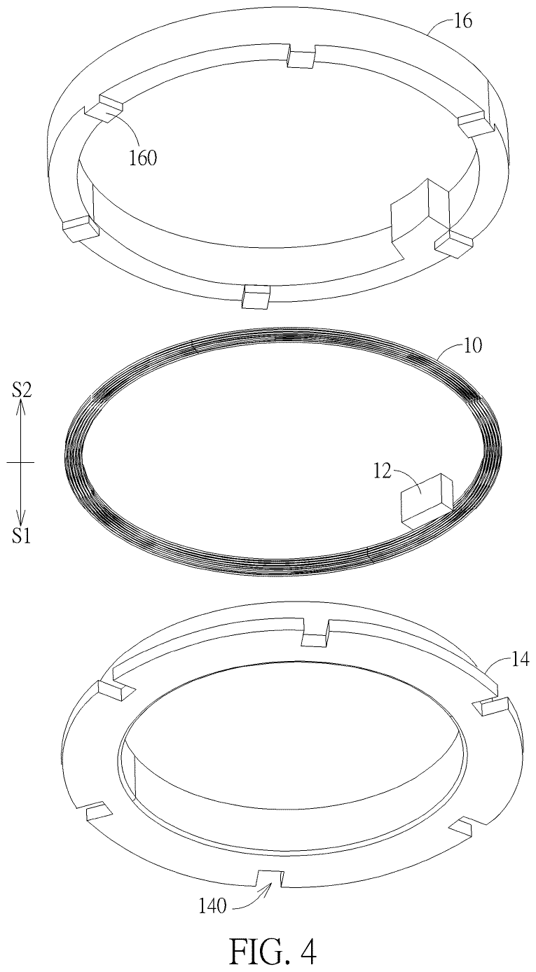

Referring to FIGS. 1 to 4, FIG. 1 is a perspective view illustrating an electronic package structure 1 according to an embodiment of the invention, FIG. 2 is an exploded view illustrating the electronic package structure 1 shown in FIG. 1, FIG. 3 is a perspective view illustrating the electronic package structure 1 shown in FIG. 1 from another viewing angle, and FIG. 4 is an exploded view illustrating the electronic package structure 1 shown in FIG. 3.

As shown in FIGS. 1 to 4, the electronic package structure 1 comprises a ring-shaped electronic component 10, a chip 12, a first frame 14 and a second frame 16. The chip 12 is coupled to the ring-shaped electronic component 10. The ring-shaped electronic component 10 may be a coil or a circuit board according to practical applications. The ring-shaped electronic component 10 may be used as an antenna, but the invention is not so limited. The first frame 14 covers the ring-shaped electronic component 10 and the chip 12 from a first side S1, and the second frame 16 covers the ring-shaped electronic component 10 and the chip 12 from a second side S2, wherein the first side S1 is opposite to the second side S2. The first frame 14 and the second frame 16 are combined with each other from the first side S1 and the second side S2 respectively, such that the ring-shaped electronic component 10 and the chip 12 are sealed between the first frame 14 and the second frame 16.

In other words, the invention packages the ring-shaped electronic component 10 and the chip 12 in the first frame 14 and the second frame 16 combined with each other, so as to form the electronic package structure 1. After the package is completed, there will be no holes formed in the appearance of the first frame 14 and the second frame 16. Accordingly, the ring-shaped electronic component 10 and the chip 12 are sealed between the first frame 14 and the second frame 16 combined with each other, so as to achieve complete waterproofing without exposing internal components. In this embodiment, the first frame 14 and the second frame 16 may be transparent, such that the positions of the ring-shaped electronic component 10 and the chip 12 located inside the first frame 14 and the second frame 16 may be seen after the package is completed. It should be noted that the first frame 14 and the second frame 16 are not limited to transparent.

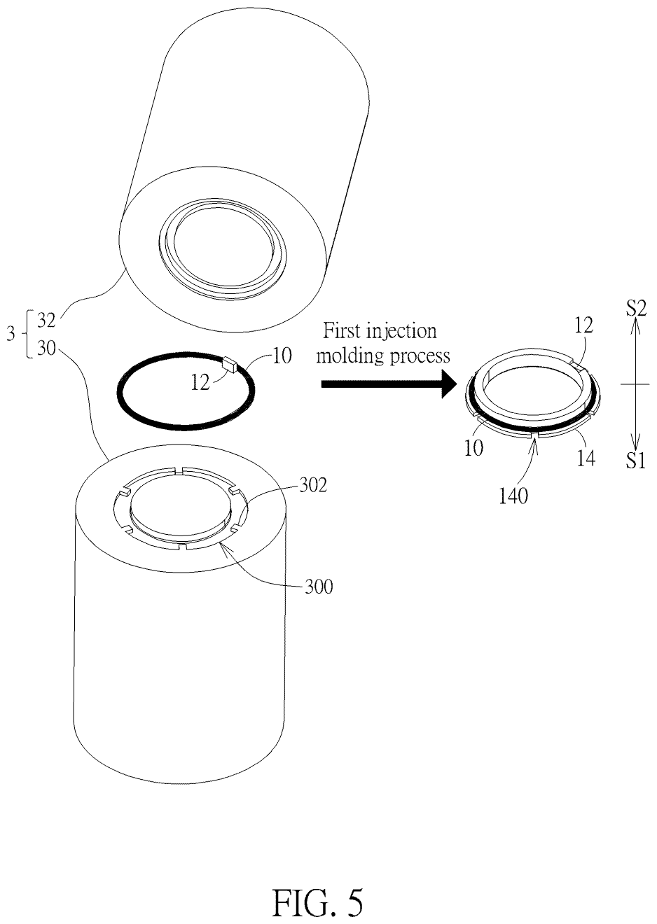

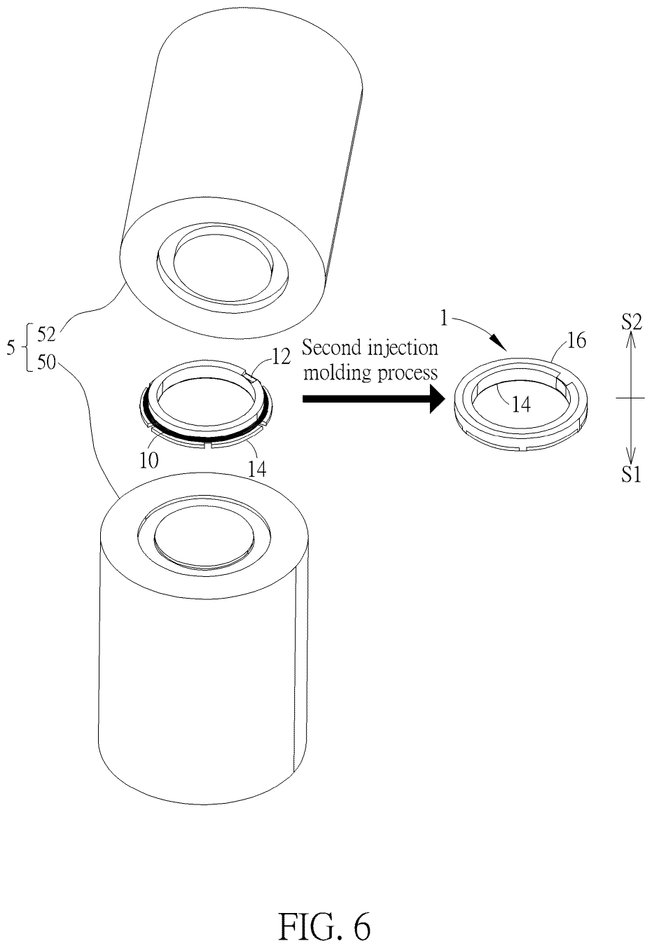

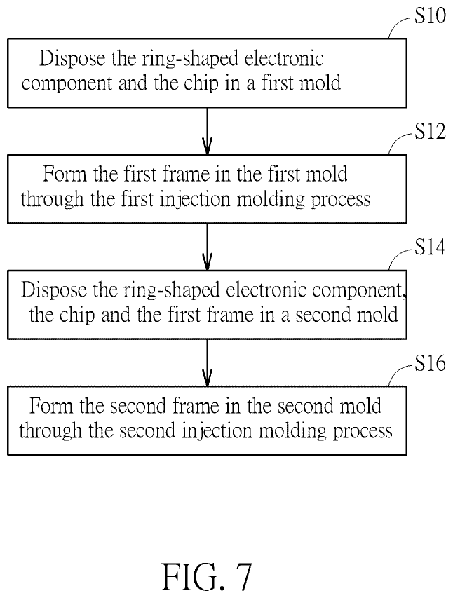

Referring to FIGS. 5 to 7, FIG. 5 is a schematic view illustrating a first injection molding process according to an embodiment of the invention, FIG. 6 is a schematic view illustrating a second injection molding process according to an embodiment of the invention, and FIG. 7 is a flowchart illustrating a method of manufacturing the electronic package structure 1 according to an embodiment of the invention.

In this embodiment, the first frame 14 may be formed through a first injection molding process first, as shown in FIG. 5. Then, the second frame 16 may be formed through a second injection molding process, as shown in FIG. 6. In the following, the method of manufacturing the electronic package structure 1 shown in FIG. 7 is depicted along with FIGS. 5 and 6.

First, step S10 is performed to dispose the ring-shaped electronic component 10 and the chip 12 in a first mold 3, as shown in FIG. 5. In this embodiment, the first mold 3 may comprise a first male mold 30 and a first female mold 32. The first male mold 30 may be formed with a plurality of grooves 300 and a plurality of protruding portions 302, wherein the plurality of grooves 300 and the plurality of protruding portions 302 are arranged in a ring shape at intervals. The ring-shaped electronic component 10 may be disposed on the protruding portions 302, such that the protruding portions 302 support the ring-shaped electronic component 10 above the grooves 300. Then, the first female mold 32 is covered on the first male mold 300. Then, step S12 is performed to form the first frame 14 in the first mold 3 through the first injection molding process, such that the first frame 14 covers the ring-shaped electronic component 10 and the chip 12 from the first side S1. Since the protruding portions 302 support the ring-shaped electronic component 10 above the grooves 300, a side of the first frame 14 will be formed with a plurality of recesses 140 during the first injection molding process, wherein positions of the plurality of recesses 140 correspond to positions of the plurality of protruding portions 302 of the first male mold 30.

Then, the ring-shaped electronic component 10, the chip 12 and the first frame 14 are taken out of the first mold 3. Then, step S14 is performed to dispose the ring-shaped electronic component 10, the chip 12 and the first frame 14 in a second mold 5, as shown in FIG. 6. In this embodiment, the second mold 5 may comprise a second male mold 50 and a second female mold 52. The ring-shaped electronic component 10, the chip 12 and the first frame 14 may be disposed in the second male mold 50 first and then the second female mold 52 is covered on the second male mold 50. When the ring-shaped electronic component 10, the chip 12 and the first frame 14 are disposed in the second male mold 50, the first frame 14 is in contact with the second male mold 50 the ring-shaped electronic component 10 is not in contact with the second male mold 50. Then, step S16 is performed to form the second frame 16 in the second mold 5 through the second injection molding process, such that the second frame 16 covers the ring-shaped electronic component 10 and the chip 12 from the second side S2. At this time, the first frame 14 and the second frame 16 are combined with each other, such that the ring-shaped electronic component 10 and the chip 12 are sealed between the first frame 14 and the second frame 16. Since a side of the first frame 14 is formed with a plurality of recesses 140 during the first injection molding process, a side of the second frame 16 is formed with a plurality of protrusions 160 (as shown in FIG. 4) during the second injection molding process, wherein positions of the plurality of protrusions 160 correspond to positions of the plurality of recesses 140. Thus, after the second frame 16 is formed, the plurality of protrusions 160 of the second frame 16 are embedded in the plurality of recesses 140 of the first frame 14 (as shown in FIG. 3), so as to ensure that the ring-shaped electronic component 10 and the chip 12 are not exposed. Accordingly, the ring-shaped electronic component 10 and the chip 12 are sealed between the first frame 14 and the second frame 16 combined with each other, so as to achieve complete waterproofing without exposing internal components.

In this embodiment, the materials of the first frame 14 and the second frame 16 may be plastic or other materials suitable for injection molding.

As mentioned in the above, the invention packages the ring-shaped electronic component and the chip in the first frame and the second frame combined with each other. In an embodiment, the first frame may be formed through the first injection molding process first to cover the ring-shaped electronic component and the chip. At this time, the first frame can fix the ring-shaped electronic component with insufficient rigidity to prevent the ring-shaped electronic component from deforming. Then, the second frame may be formed through the second injection molding process, such that the first frame and the second frame are combined with each other. After the package is completed, there will be no holes formed in the appearance of the first frame and the second frame. Accordingly, the ring-shaped electronic component and the chip are sealed between the first frame and the second frame combined with each other, so as to achieve complete waterproofing without exposing internal components. The electronic package structure of the invention not only has fast processing speed, but also the mold can be modularized to increase production efficiency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic package structure comprising:
a ring-shaped electronic component;
a chip coupled to the ring-shaped electronic component;
a first frame covering the ring-shaped electronic component and the chip from a first side; and
a second frame covering the ring-shaped electronic component and the chip from a second side, the first side being opposite to the second side;
wherein the first frame and the second frame are combined with each other, such that the ring-shaped electronic component and the chip are sealed between the first frame and the second frame.

2. The electronic package structure of claim 1, wherein the first frame is formed through a first injection molding process first and then the second frame is formed through a second injection molding process.

3. The electronic package structure of claim 2, wherein a side of the first frame is formed with a plurality of recesses during the first injection molding process, a side of the second frame is formed with a plurality of protrusions during the second injection molding process, and the plurality of protrusions are embedded in the plurality of recesses.

4. The electronic package structure of claim 1, wherein the ring-shaped electronic component is a coil or a circuit board.

5. The electronic package structure of claim 1, wherein the first frame and the second frame are transparent.

6. A method of manufacturing an electronic package structure comprising steps of:
disposing a ring-shaped electronic component and a chip in a first mold, wherein the chip is coupled to the ring-shaped electronic component;
forming a first frame in the first mold through a first injection molding process, such that the first frame covers the ring-shaped electronic component and the chip from a first side;
disposing the ring-shaped electronic component, the chip and the first frame in a second mold; and
forming a second frame in the second mold through a second injection molding process, such that the second frame covers the ring-shaped electronic component and the chip from a second side, the first frame and the second frame are combined with each other, and the ring-shaped electronic component and the chip are sealed between the first frame and the second frame, wherein the first side is opposite to the second side.

7. The method of claim 6, wherein the first mold comprises a first male mold and a first female mold, the first male mold is formed with a plurality of grooves and a plurality of protruding portions, the plurality of grooves and the plurality of protruding portions are arranged in a ring shape at intervals, the step of disposing a ring-shaped electronic component and a chip in a first mold comprises steps of:
disposing the ring-shaped electronic component on the plurality of protruding portions, such that the plurality of protruding portions support the ring-shaped electronic component above the plurality of grooves; and
covering the first female mold on the first male mold.

8. The method of claim 7, wherein a side of the first frame is formed with a plurality of recesses during the first injection molding process, and positions of the plurality of recesses correspond to positions of the plurality of protruding portions of the first male mold.

9. The method of claim 8, wherein a side of the second frame is formed with a plurality of protrusions during the second injection molding process, and the plurality of protrusions are embedded in the plurality of recesses.

10. The method of claim 6, wherein the second mold comprises a second male mold and a second female mold, the step of disposing the ring-shaped electronic component, the chip and the first frame in a second mold comprises steps of:
disposing the ring-shaped electronic component, the chip and the first frame in the second male mold, such that the first frame is in contact with the second male mold, and the ring-shaped electronic component is not in contact with the second male mold; and
covering the second female mold on the second male mold.

11. The method of claim 6, wherein the ring-shaped electronic component is a coil or a circuit board.

12. The method of claim 6, wherein the first frame and the second frame are transparent.
